(19) United States
(12) Patent Application Publication
(10) Pub. No.: US 2008/0054400 A1
(43) Pub. Date: Mar. 6, 2008

(54) Capacitor and method of manufacturing the same

(75) Inventors: Woo-Sung Lee, Yongin-si (KR); Hong-Bum Park, Suwon-si (KR); Hyun-Jin Shin, Seoul (KR); Jong-Bom Seo, Seoul (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/878,698

(22) Filed: Jul. 26, 2007

(30) Foreign Application Priority Data
Sep. 5, 2006 (KR) 10-2006-0085177

(51) Int. Cl. H01L 29/92; H01L 21/02

(52) U.S. Cl. 257/532; 438/396; 257/E29.342; 257/E21.011

(57) ABSTRACT

Example embodiments relate to a capacitor including p-type doped silicon germanium and a method of manufacturing the capacitor. The capacitor may include a lower electrode, a dielectric layer, an upper electrode, a barrier layer and a capping layer. The lower electrode may have a cylindrical shape. The dielectric layer may be on the lower electrode. The dielectric layer may have a uniform thickness. The upper electrode may be on the dielectric layer. The upper electrode may have a more uniform thickness. The capping layer may be on the upper electrode. The capping layer may include a silicon germanium layer doped with p-type impurities. The barrier layer may be between the upper electrode and the capping layer to prevent (or reduce) the p-type impurities from infiltrating into the dielectric layer.

### PRIORITY STATEMENT

This application claims the benefit of priority under 35 USC § 119 to Korean Patent Application No. 2006-85177 filed on Sep. 5, 2006, the contents of which are herein incorporated by reference in its entirety.

### BACKGROUND

1. Field

Example embodiments relate to a capacitor and a method of manufacturing the same. Other example embodiments relate to a capacitor including p-type doped silicon germanium and a method of manufacturing the capacitor.

2. Description of the Related Art

Generally, a dynamic random access memory (DRAM) device may include an access transistor and a storage capacitor that together function as a unit cell. The size of the capacitor may be decreased so that a more highly-integrated semiconductor device may be formed. Manufacturing a capacitor with a higher storage capacity and a smaller size has been the focus of recent research.

As known in the industry, the storage capacity of the capacitor may be represented by the following Equation (1):

C=(∈ₒ)(∈)(A/d) EQUATION (1)

In Equation (1), ∈ₒ represents a dielectric constant under vacuum, ∈ represents a dielectric constant of a dielectric layer, A represents an effective area of a lower electrode and d represents a thickness of the dielectric layer.

Referring to Equation 1, increasing the storage capacity of the capacitor may include increasing the effective area of the lower electrode, decreasing the thickness of the dielectric layer, using a material having a high dielectric constant as the dielectric layer, etc. In order to increase the effective area of the lower electrode, the lower electrode of the capacitor may be formed with a cylindrical shape. The width of the lower electrode may be larger than the height of the lower electrode. Methods of manufacturing a capacitor with a cylindrical lower electrode are known in the art.

In the method of manufacturing the cylindrical lower electrode of the capacitor, cylindrical lower electrodes having separated nodes may be formed on a semiconductor substrate. The cylindrical lower electrodes may have a large aspect ratio. The cylindrical lower electrodes may be arranged adjacent to each other. An insulation interlayer having a contact pad may be formed on the semiconductor substrate. The cylindrical lower electrodes may be connected to the contact pad. A dielectric layer having a uniform thickness may be formed on the lower electrodes. A metal layer and a silicon germanium layer doped with boron or phosphorous may be sequentially formed on the dielectric layer.

The silicon germanium layer of the capacitor may be formed by depositing silicon germanium on the metal layer and/or crystallizing the silicon germanium in order that performing a thermal treatment on the silicon germanium layer is not necessary. Thermal stresses applied to the dielectric layer and the capacitor may decrease so that the dielectric layer may be more reliable. If the silicon germanium layer is doped with the boron, the silicon germanium may decrease noises between patterns of a semiconductor device in order that the semiconductor device may have desired refresh characteristics. Because the boron in the silicon germanium layer may rapidly diffuse, the boron may infiltrate in the dielectric layer due to thermal treatments in subsequent processes.

The boron infiltrating into the dielectric layer functions as a charge-trapping site in the dielectric layer, causing increased leakage currents and/or decreased reliability of the dielectric layer.

### SUMMARY

Example embodiments relate to a capacitor and a method of manufacturing the same. Other example embodiments relate to a capacitor including p-type doped silicon germanium and a method of manufacturing the capacitor.

Example embodiments provide a capacitor having a barrier layer that prevents (or reduces) infiltration of p-type impurities into a dielectric layer in manufacturing the capacitor having a p-type doped silicon germanium layer and a method of manufacturing the same.

A capacitor in accordance with example embodiments includes a lower electrode, a dielectric layer, an upper electrode, a barrier layer and a capping layer. The lower electrode may have a cylindrical shape. The dielectric layer may be on the lower electrode. The dielectric layer may have a more uniform thickness. The upper electrode may be on the dielectric layer. The upper electrode may have a more uniform thickness. The capping layer may be on the upper electrode. The capping layer may include a silicon germanium layer doped with p-type impurities. The barrier layer may be between the upper electrode and the capping layer to prevent (or reduce) infiltration of the p-type impurities into the dielectric layer.

According to example embodiments, the barrier layer may include a nitride layer having a thickness of about 30 Å to about 80 Å. The capping layer may include a seed layer (e.g., a silicon layer, a silicon germanium layer, a composite layer thereof). The lower electrode and the upper electrode may include titanium nitride. The impurities may include boron.

In a method of manufacturing a capacitor in accordance with example embodiments, a lower electrode may be on a substrate. A dielectric layer having a more uniform thickness may be on the lower electrode. An upper electrode having a more uniform thickness may be on the dielectric layer. A barrier layer for preventing (or reducing) p-type impurities from infiltrating into the dielectric layer in a subsequent process may be on the upper electrode. A capping layer including a silicon germanium layer doped with the p-type impurities may be on the upper electrode.

In a method of manufacturing a capacitor in accordance with example embodiments, a substrate having a conductive structure may be prepared. A mold layer pattern having an opening that exposes an upper face of the conductive structure may be formed on the substrate. A conductive layer having a uniform thickness may be formed on the mold layer pattern and/or an inner face of the opening. A buffer layer may be formed on the conductive layer to fill up the opening having the conductive layer. The buffer layer may be removed until the conductive layer on the mold layer pattern is exposed to form a buffer layer pattern. The conductive layer on the mold layer pattern may be etched using the buffer layer pattern as an etching mask to form a lower electrode. The mold layer pattern and the buffer layer pattern may be removed to expose the lower electrode on the substrate. A dielectric layer having a more uniform thickness may be formed on the lower electrode. An upper electrode having a more uniform thickness may be formed on the dielectric layer. A barrier layer for preventing (or reducing) infiltration of p-type impurities into the dielectric layer during a following process may be formed on the upper electrode. A capping layer including a silicon germanium layer doped with the p-type impurities may be formed on the upper electrode.

According to example embodiments, the barrier layer may be obtained (or formed) by thermally treating the upper electrode at a temperature of about 800° C. to about 1,100° C. under a gas atmosphere that includes N₂, NO, N₂O, NH₃ or the like. The barrier layer may be obtained (or formed) by forming plasma from a gas that includes N₂, NO, N₂O, NH₃ or the like. The barrier layer may be obtained (or formed) by plasma-nitrifying a surface of the upper electrode using the plasma.

According to example embodiments, the capping layer may include a silicon layer and a silicon germanium layer dopes with the p-type impurities. The silicon layer and the silicon germanium layer doped with the p-type impurities may be formed in-situ. The capping layer may include a silicon germanium layer. The silicon germanium layer and the silicon germanium layer doped with the p-type impurities may be formed in-situ. The silicon layer, the silicon germanium layer and the silicon germanium layer doped with the p-type impurities may be formed in-situ.

According to example embodiments, the barrier layer including nitride may be formed on the upper electrode. The barrier layer may prevent (or reduce) the p-type impurities in the silicon germanium layer from infiltrating into the dielectric layer while performing subsequent thermal treatment(s). A charge-trapping site may not exist in the dielectric layer, increasing the reliability of the dielectric layer. As such, leakage currents may be suppressed in order that the capacitor may have increased electrical characteristics.

### BRIEF DESCRIPTION OF THE DRAWINGS

Example embodiments will be more clearly understood from the following detailed description taken in conjunction with the accompanying drawings. FIGS. 1-13 represent non-limiting, example embodiments as described herein.

FIG. 1 is a diagram illustrating a cross-sectional view of a capacitor in accordance with example embodiments;

FIG. 2 is a flow chart illustrating a method of manufacturing the capacitor in FIG. 1;

FIG. 3 is a diagram illustrating a cross-sectional view of a capacitor in accordance with example embodiments;

FIG. 4 is a flow chart illustrating a method of manufacturing the capacitor in FIG. 3;

FIGS. 5 to 12 are diagrams illustrating cross-sectional views of a method of manufacturing a semiconductor device in accordance with example embodiments; and

FIG. 13 is a graph showing concentrations of boron in dielectric layers in Examples 1 and 2 and Comparative Example.

### DESCRIPTION OF EXAMPLE EMBODIMENTS

Various example embodiments will now be described more fully with reference to the accompanying drawings in which some example embodiments are shown. In the drawings, the thicknesses of layers and regions may be exaggerated for clarity.

Detailed illustrative embodiments are disclosed herein. However, specific structural and functional details disclosed herein are merely representative for purposes of describing example embodiments. This invention may, however, may be embodied in many alternate forms and should not be construed as limited to only example embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but on the contrary, example embodiments are to cover all modifications, equivalents, and alternatives falling within the scope of the invention. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the scope of example embodiments.

Spatially relative terms, such as “beneath,” “below,” “lower,” “above,” “upper” and the like, may be used herein for ease of description to describe one element or a relationship between a feature and another element or feature as illustrated in the figures. It will be understood that the spatially relative terms are intended to encompass different orientations of the device in use or operation in addition to the orientation depicted in the Figures. For example, if the device in the figures is turned over, elements described as “below” or “beneath” other elements or features would then be oriented “above” the other elements or features. Thus, for example, the term “below” can encompass both an orientation which is above as well as below. The device may be otherwise oriented (rotated 90 degrees or viewed or referenced at other orientations) and the spatially relative descriptors used herein should be interpreted accordingly.

Example embodiments are described herein with reference to cross-sectional illustrations that are schematic illustrations of idealized embodiments (and intermediate structures). As such, variations from the shapes of the illustrations as a result, for example, of manufacturing techniques and/or tolerances, may be expected. Thus, example embodiments should not be construed as limited to the particular shapes of regions illustrated herein but may include deviations in shapes that result, for example, from manufacturing. For example, an implanted region illustrated as a rectangle may have rounded or curved features and/or a gradient (e.g., of implant concentration) at its edges rather than an abrupt change from an implanted region to a non-implanted region. Likewise, a buried region formed by implantation may result in some implantation in the region between the buried region and the surface through which the implantation may take place. Thus, the regions illustrated in the figures are schematic in nature and their shapes do not necessarily illustrate the actual shape of a region of a device and do not limit the scope.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In order to more specifically describe example embodiments, various aspects will be described in detail with reference to the attached drawings. However, the present invention is not limited to example embodiments described.

Example embodiments relate to a capacitor and a method of manufacturing the same. Other example embodiments relate to a capacitor including p-type doped silicon germanium and a method of manufacturing the capacitor.

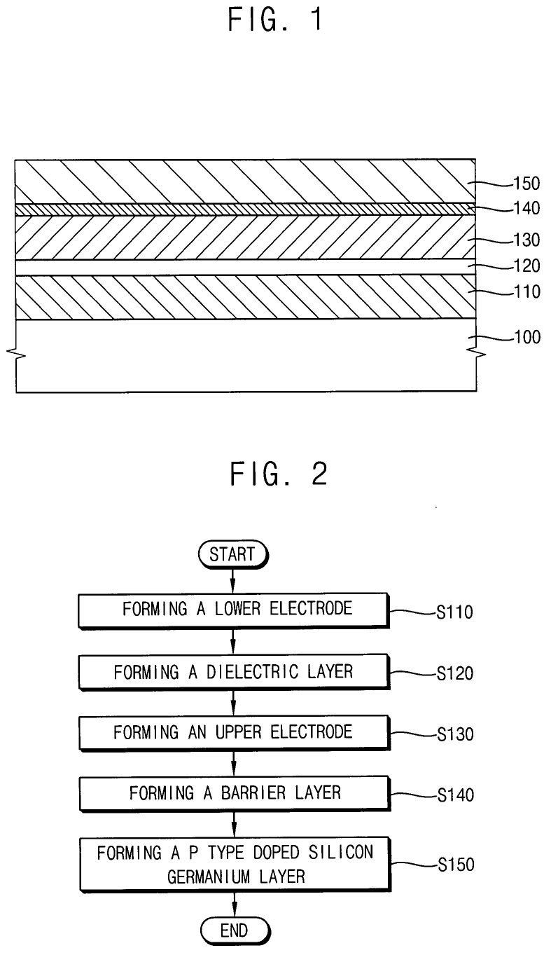

FIG. 1 is a diagram illustrating a cross-sectional view of a capacitor in accordance with example embodiments. FIG. 2 is a flow chart illustrating a method of manufacturing the capacitor in FIG. 1.

Referring to FIG. 1, a capacitor includes a lower electrode 110, a dielectric layer 120, an upper electrode 130, a barrier layer 140 and a capping layer 150 having a p-type doped silicon germanium layer.

Referring to FIGS. 1 and 2, the lower electrode 110 may be formed by depositing a conductive material on a semiconductor substrate 100 (S110).

The conductive material may, for example, include titanium, titanium nitride, tantalum, tantalum nitride, tungsten, tungsten nitride or the like. The titanium nitride may be used for the lower electrode 110. The lower electrode 110 may have a cylindrical shape.

The dielectric layer 120 may be formed on the lower electrode 110 (S120).

The dielectric layer 120 may have a more uniform thickness. The dielectric layer 120 may, for example, include oxide-nitride, oxide-nitride-oxide, metal oxide or the like. The metal oxide may, for example, include HfO₂, ZrO₂, Ta₂O₅, Y₂O₃, Nb₂O₅, Al₂O₃, TiO₂, CeO₂, In₂O₃, RuO₂, MgO, SrO, B₂O₃, SnO₂, PbO, PbO₂, Pb₃O₄, V₂O₃, La₂O₃, Pr₂O₃, Sb₂O₃, Sb₂O₅, CaO or combinations thereof. The dielectric layer 120 that includes the metal oxide may have desirable leakage current characteristics and/or may be capable of decreasing an equivalent oxide thickness (EOT).

The upper electrode 130 may be formed on the dielectric layer 120 (S130).

A conductive material may be deposited (or formed) on the dielectric layer 120 to form the upper electrode 130 having a more uniform thickness. The upper electrode 130 may have a thickness of about 100 Å to about 300 Å. The conductive material of the upper electrode 130 may be substantially the same as that of the lower electrode 110. The upper electrode 130 may be formed by a chemical vapor deposition (CVD) process using the titanium nitride at a temperature of about 700° C.

The barrier layer 140 may be formed on the upper electrode 130 (S140). The barrier layer 140 prevents (or reduces) p-type impurities in the silicon germanium layer from infiltrating in the dielectric layer 120 by means of the upper electrode 130. The barrier layer 140 includes a nitride layer. The barrier layer 140 may be formed by thermally nitrifying or plasma-nitrifying a surface of the upper electrode 130. The barrier layer 140 may have a denser structure.

The thermal nitrification may be performed on the surface of the upper electrode 130 at a temperature of about 800° C. to about 1,100° C. under a gas atmosphere that includes N₂, NO, N₂O, NH₃ or the like. The plasma nitrification may be performed on the surface of the upper electrode 130 using plasma that is generated from a gas including N₂, NO, N₂O, NH₃ or the like.

The capping layer 150 including the p-type doped silicon germanium layer may be formed on the barrier layer 140 (S150).

The p-type doped silicon germanium layer may be formed by a low pressure chemical vapor deposition (LPCVD) process using a silicon source gas, a germanium source gas, p-type impurities or the like. The silicon source gas may, for example, include a tetrachlorosilane (SiCl₄) gas, a silane (SiH₄) gas, a dichlorosilane (SiH₂Cl₂) gas, a trichlorosilane (SiHCl₃) gas or the like. The silicon germanium source gas may, for example, include a germane (GeH₄) gas, a germanium tetrafluoride (GeF₄) gas or the like. The p-type impurities may, for example, include boron in boron trichloride (BCl₃), boron hydride (B₂H₆) or the like. The p-type doped silicon germanium layer may include a boron doped silicon germanium layer having boron ions of about 1×10²⁰ ion/cm³ to about 8×10²⁰ ion/cm³.

According to example embodiments, the boron in the capping layer 150 may not infiltrate into the dielectric layer 120 because the capacitor includes the barrier layer 140. Leakage currents generated in the capacitor may be suppressed (or decreased) in order to increase the reliability of the capacitor.

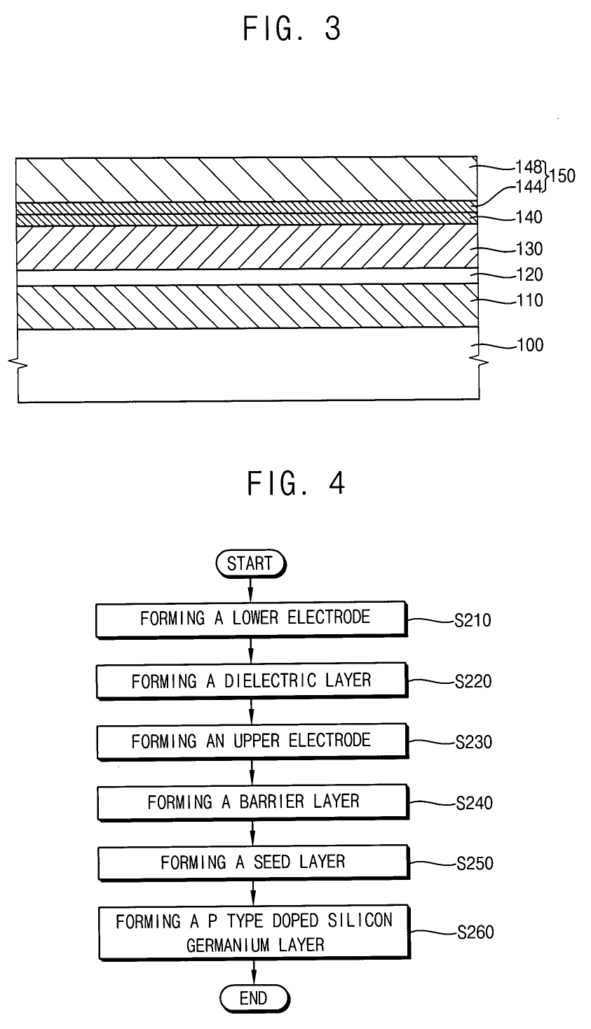

FIG. 3 is diagram illustrating a cross-sectional view of a capacitor in accordance with example embodiments. FIG. 4 is a flow chart illustrating a method of manufacturing the capacitor in FIG. 3. Here, like elements in FIGS. 1 and 3 are referred to using the same reference numerals. Thus, a description of like elements in FIGS. 1 and 3 will be omitted herein for brevity.

Referring to FIGS. 3 and 4, a capacitor includes a lower electrode 110, a dielectric layer 120, an upper electrode 130, a barrier layer 140 and a capping layer 150. The capping layer 150 may include a seed layer 144 and a p-type doped silicon germanium layer 148.

A conductive material may be deposited on a semiconductor substrate to form the lower electrode 110 (S210). In example embodiments, the lower electrode 110 may have a cylindrical shape and/or a more uniform thickness.

The dielectric layer 120 may be formed on the lower electrode 110 (S220). The dielectric layer may have a more uniform thickness. The dielectric layer 120 may have a structure including a first oxide layer, a nitride layer and a second oxide layer that are sequentially stacked.

The upper electrode 130 may be formed on the dielectric layer 120 (S230). The upper electrode 130 may have a more uniform thickness. The upper electrode 130 may be formed using titanium nitride substantially the same as that used in the lower electrode 110.

The barrier layer 140 may be formed on the upper electrode 130 (S240).

The barrier layer 140 prevents (or reduces) p-type impurities in the silicon germanium layer from infiltrating into the dielectric layer 120 through the upper electrode 130. The barrier layer 140 includes a nitride layer. The barrier layer 140 may be formed by thermally nitrifying or plasma-nitrifying a surface of the upper electrode 130. The barrier layer 140 may be formed by the thermal nitrification process.

The semiconductor substrate having the upper electrode 130 may be loaded into a chamber (not shown). A nitrification gas including nitrogen may be introduced into the chamber to thermally decompose the nitrification gas. The nitrification gas may, for example, include N₂, NO, N₂O, NH₃ or the like. The surface of the upper electrode 130 may be nitrified using nitrogen atoms generated from the thermally decomposed nitrification gas in the chamber. The nitride layer may be formed on the upper electrode 130. The nitride layer may correspond to the barrier layer 140.

The seed layer 144 may be formed on the barrier layer 140 (S250).

A silicon germanium layer may be formed on the barrier layer 140 as the seed layer 144. The silicon germanium layer may be formed by an LPCVD process using a silicon source gas and a germanium source gas. The silicon source gas and the germanium source gas may be substantially the same as those described above. Any further description of with respect to the silicon source gas and the germanium source gas will be omitted herein for the sake of brevity. The silicon germanium layer as the seed layer 144 prevents (or reduces) particles in a boron doped silicon germanium layer from excessively growing while forming the boron doped silicon germanium layer.

The p-type doped silicon germanium layer 148 may be formed on the barrier layer 140. The p-type doped silicon germanium layer may be formed by a low pressure chemical vapor deposition (LPCVD) process using a silicon source gas, a germanium source gas, p-type impurities or the like. The p-type impurities may, for example, include boron trichloride (BCl₃), boron hydride (B₂H₆) or the like. The p-type doped silicon germanium layer may include a boron doped silicon germanium layer having boron ions of about 1×10²⁰ ion/cm³ to about 8×10²⁰ ion/cm³. The capping layer 150, which includes the silicon germanium layer 144 as the seed layer and the p-type doped silicon germanium layer 148, may be formed on the barrier layer 140.

According to example embodiments, the p-type doped silicon germanium layer 148 may not excessively grow and the p-type impurities in the p-type doped silicon germanium layer 148 also may not infiltrate into the dielectric layer 120 because the capacitor includes the barrier layer 140 and the seed layer 144.

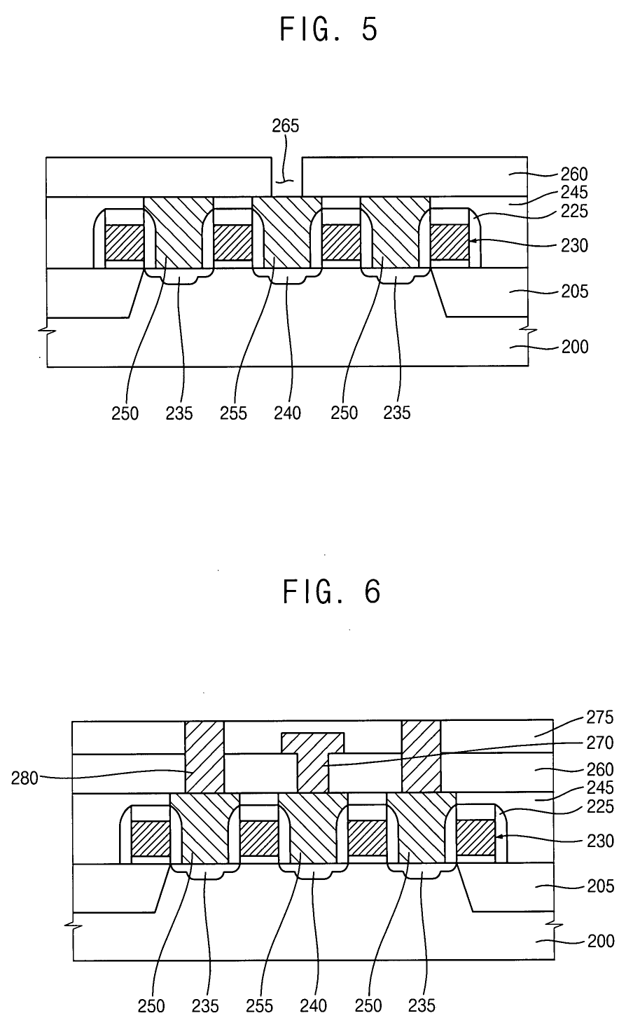

FIGS. 5 to 12 are diagrams illustrating cross-sectional views of a method of manufacturing a semiconductor device in accordance example embodiments.

Referring to FIG. 5, an isolation layer 205 may be formed in a semiconductor substrate 200 by a shallow trench isolation (STI) process to define an active region and a field region of the semiconductor substrate 200.

A gate insulation layer (not shown) may be formed on the semiconductor substrate 200 having the isolation layer 205 by a thermal oxidation process, a chemical vapor deposition (CVD) process, an atomic layer deposition (ALD) process or the like. The gate insulation layer may include a silicon oxide layer. The gate insulation layer may include a layer having a dielectric constant larger than that of the silicon oxide layer.

The gate insulation layer may, for example, be formed of HfO₂, ZrO₂, Ta₂O₅, Y₂O₃, Nb₂O₅, Al₂O₃, TiO₂, CeO₂, In₂O₃, RuO₂, MgO, SrO, B₂O₃, SnO₂, PbO, PbO₂, Pb₃O₄, V₂O₃, La₂O₃, Pr₂O₃, Sb₂O₃, Sb₂O₅, CaO or combinations thereof.

A first conductive layer (not shown) and a gate mask layer (not shown) may be sequentially formed on the gate insulation layer. The first conductive layer may include a polysilicon layer doped with impurities. The first conductive layer may be patterned to form a gate electrode. The first conductive layer may include a polysilicon layer doped with impurities and a metal silicide layer.

The gate mask layer may include a material having an etching selectivity higher than that of a first insulation interlayer 245. If the first insulation interlayer 245 includes an oxide layer (e.g., a silicon oxide layer), the gate mask layer may include a silicon nitride layer.

The first conductive layer and the gate insulation layer may be etched using the gate mask layer as an etching mask to form a gate structure 230 including a gate insulation layer pattern (not shown), a gate electrode (not shown) and the gate mask layer on the semiconductor substrate 200.

A silicon nitride layer (not shown) may be formed on the semiconductor substrate 200 having the gate structure 230. The silicon nitride layer may be anisotropically etched to form a gate spacer 225 on a sidewall of the gate structure 230.

Impurities may be implanted into the semiconductor substrate 200 using the gate structure 230 having the gate spacer 225 as an ion implantation mask. The semiconductor substrate 200 may be thermally treated to form a first contact region 235 and a second contact region 240 in the semiconductor substrate 200 corresponding to a source region and a drain region, respectively.

The first contact region 235 and the second contact region 240 may be divided into a capacitor contact region and a bit line contact region. The capacitor contact region may contact a first pad 250 for a capacitor and the bit line contact region may contact a second pad 255 for a bit line. The first contact region 235 may correspond to the capacitor contact region contacting the first pad 250. The second contact region 240 may correspond to the bit line contact region contacting the second pad 255. A transistor including the gate structure 230, the gate spacer 225, the first contact region 235 and the second contact region 240 may be formed on the semiconductor substrate 200.

The first insulation interlayer 245 including oxide may be formed on the semiconductor substrate 200 to cover (or over) the gate structure 230. The first insulation interlayer 245 may be formed by a CVD process, a plasma-enhanced chemical vapor deposition (PECVD) process, a high density chemical vapor deposition (HDCVD) process or similar process. The first insulation interlayer 245 may be formed using BOSS, PSG, SOG, PE-TEOS, USG, HDP-CVD or the like.

A surface portion of the first insulation interlayer 245 may be removed by a chemical mechanical polishing (CMP) process to planarize the surface of the first insulation interlayer 245. A height of the planarized first insulation interlayer 245 may be measured from an upper face of the gate mask layer.

A second photoresist pattern (not shown) may be formed on the planarized first insulation interlayer 245. The first insulation interlayer may be anisotropically etched using the second photoresist pattern as an etching mask to form first contact holes (not shown) through the first insulation interlayer 245 that expose the first contact region 235 and the second contact region 240. The first contact holes may be self-aligned with respect to the gate structure 230 to expose the first contact region 235 and the second contact region 240.

Some of the first contact holes may expose the first contact region 235 corresponding to the capacitor contact region. The remaining first contact holes may expose the second contact region 240 corresponding to the bit line contact region.

The second photoresist pattern may be removed by an ashing process and/or a stripping process. A second conductive layer (not shown) may be formed on the first insulation interlayer 245 to fill up the first contact holes. The second conductive layer may include a polysilicon layer doped with impurities, a metal layer, a conductive metal nitride layer or the like.

A CMP process or an etch-back process may be performed until an upper face of the first insulation interlayer 245 is exposed to form a first pad 250 and a second pad 255 in the first contact holes. The first pad 250 and the second pad 255 may correspond to a self-aligned contact (SAC). The first pad 250 may be formed in the first contact region 235 corresponding to the capacitor contact region. The second pad 255 may be formed in the second contact region 240 corresponding to the bit line contact region. The first pad 250 electrically contacts (or connects) the capacitor contact region and the second pad 255 electrically contacts (or connects) the bit line contact region.

A second insulation interlayer 260 may be formed on the first insulation interlayer 245 having the first pads 250 and the second pads 255. The second insulation interlayer 260 electrically isolates the first pad 250 from a bit line (not shown) that is formed later. The second insulation interlayer 260 may be formed by a CVD process, a plasma-enhanced chemical vapor deposition (PECVD) process, a high density chemical vapor deposition (HDCVD) process or a similar process. The second insulation layer 260 may be formed using BOSS, PSG, SOG, PE-TEOS, USG, HDP-CVD or the like.

The first insulation interlayer 245 and the second insulation interlayer 260 may be formed from substantially the same material selected from the above-mentioned oxide materials. The first insulation interlayer 245 and the second insulation interlayer 260 may include different materials selected from the above-mentioned oxide materials.

A surface of the second insulation interlayer 260 may be planarized by a CMP process. A third photoresist pattern (not shown) may be formed on the planarized second insulation interlayer 260. The second insulation interlayer 260 may be etched using the third photoresist pattern as an etching mask to form a second contact hole 265 through the second insulation interlayer 260 exposing the second pad 255 in the first insulation interlayer 245. The second contact hole 265 corresponds to a bit line contact hole through which the bit line and the second pad 255 are electrically connected to each other.

Referring to FIG. 6, the third photoresist pattern may be removed by an ashing process and/or a stripping process. A third conductive layer (not shown) may be formed on the second insulation interlayer 260 to fill up the second contact hole 265.

A fourth photoresist pattern (not shown) may be formed on the third conductive layer. The third conductive layer may be etched using the fourth photoresist pattern as an etching mask to form the bit line 270 electrically connected to the second pad 255 through the second contact hole 265. The bit line 270 may include a first layer having a metal/metal compound layer and a second layer including a metal layer. The first layer includes a titanium/titanium nitride layer. The second layer may include a tungsten layer.

A third insulation interlayer 275 may be formed on the second insulation interlayer 260 having the bit line 270. The third insulation interlayer 275 may include BPSG, PSG, SOG, PE-TEOS, USG, HDP-CVD or the like. The third insulation interlayer 275 may include a material substantially the same as or different from that of the second insulation interlayer 260.

The third insulation interlayer 275 may be planarized by a CMP process. In order to prevent (or reduce) the generation of voids in the third insulation interlayer 275 between the adjacent bit lines 270, an insulation layer (not shown) including nitride may be formed on the bit line 270 and the second insulation interlayer 260. The third insulation interlayer 275 may be formed on the insulation layer.

A fifth photoresist pattern (not shown) may be formed on the planarized surface of the third insulation interlayer 275. The third insulation interlayer 275 and the second insulation interlayer 260 may be etched using the fifth photoresist pattern as an etching mask to form third contact holes (not shown) exposing the first pads 250. The third contact holes correspond to capacitor contact holes.

A fourth conductive layer (not shown) may be formed on the third insulation interlayer 275 to fill up the third contact holes. A CMP process may be performed to form third pads 280 in the third contact holes. The third pads 280 may include polysilicon doped with impurities. The third pads 280 electrically connect the first pad 250 to a lower electrode (not shown) formed later.

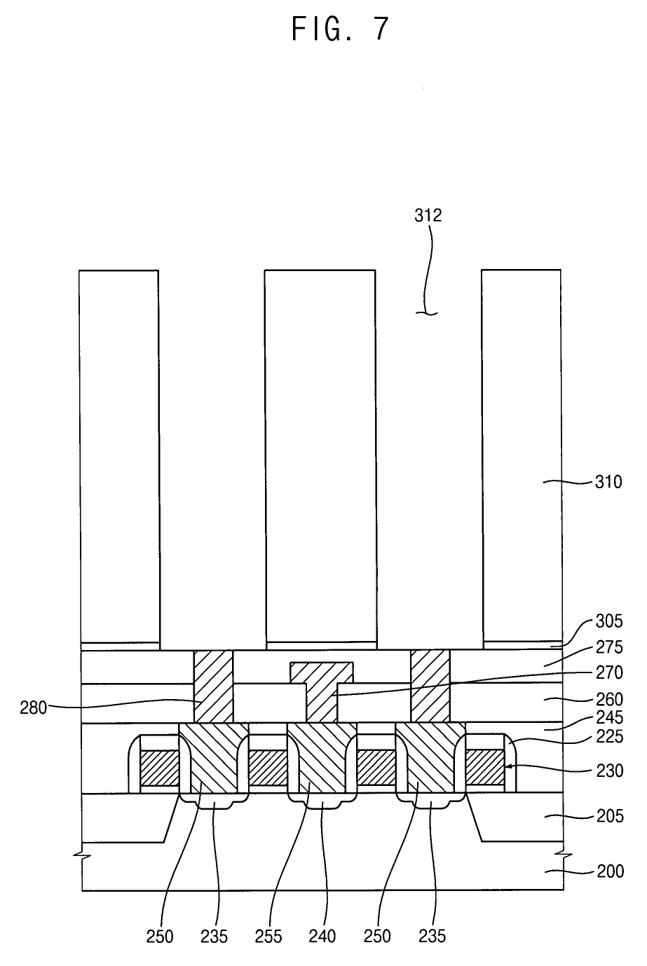

FIG. 7 is a diagram illustrating a cross-sectional view of a process for forming a mold layer pattern having an etching stop layer and an opening according to example embodiments.

Referring to FIG. 7, the etching stop layer 305 may be formed on the third pad 280 and the third insulation interlayer 275. If a mold layer 310 is etched to form the opening 312 through the mold layer 310, the etching stop layer 305 prevents (or reduces) damage to the third pad 280 while etching the mold layer 310. The etching stop layer 305 may have a thickness of about 10 Å to about 200 Å. The etching stop layer 305 may include nitride or metal oxide having a lower etching selectivity with respect to a barrier layer.

Oxide may be deposited on the etching stop layer 305 to form the mold layer 310. The mold layer 310 may include oxide (e.g., BPSG, PSG, USG, SOG, PE-TEOS or the like). The mold layer 310 may have a thickness of about 10,000 Å to about 20,000 Å. The thickness of the mold layer 310 may be adjusted in accordance with a capacitance required for the capacitor.

A mask pattern (not shown) may be formed on the mold layer 310. The mold layer 310 may be anisotropically etched using the mask pattern as an etching mask to form a mold layer pattern 310 having the openings 312 that expose a surface of the etching stop layer 305. The exposed surface of the etching stop layer 305 through the openings 312 may be etched.

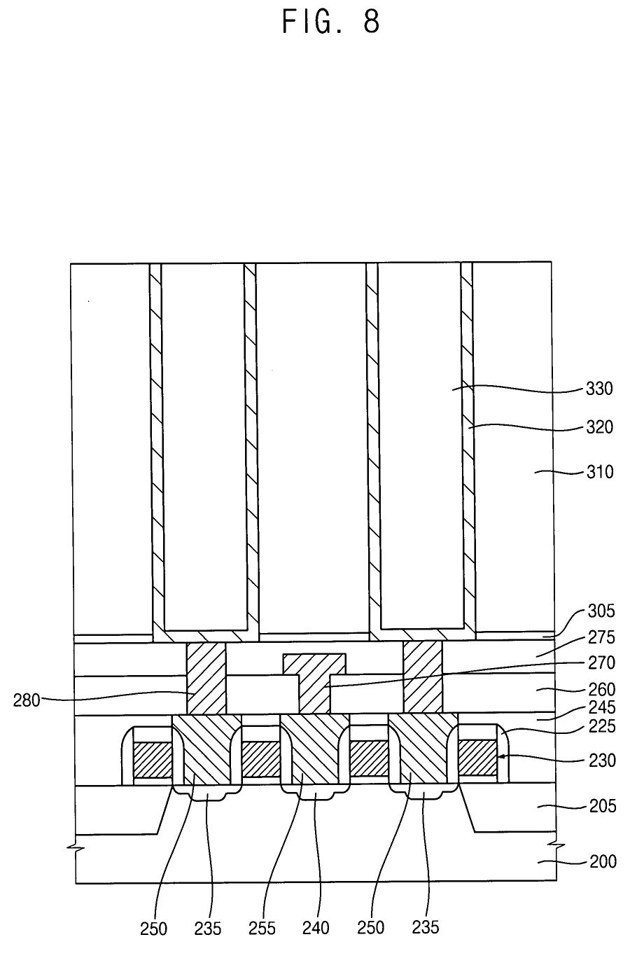

FIG. 8 is a diagram illustrating a cross-sectional view of a process for forming a buffer layer pattern according to example embodiments.

Referring to FIG. 8, a lower electrode layer (not shown) may be formed on an inner wall of the opening 312 and an upper face of the mask pattern. The opening 312 may expose a sidewall and a bottom face of the mold layer pattern 310. The lower electrode layer may include tungsten, titanium, tungsten nitride, titanium nitride or the like. The lower electrode layer may have a thickness of about 300 Å to about 500 Å.

The openings 312 having the lower electrode layer may be filled with a buffer layer (not shown). The buffer layer may include an oxide layer, a photoresist film or the like. The photoresist film may be formed by coating a photoresist composition on a clean semiconductor substrate. The photoresist composition may be baked to form a preliminary photoresist film having a stronger adhesive strength with respect to the semiconductor substrate. The preliminary photoresist film may be exposed and baked.

The resultant structure may be removed by a CMP process until an upper face of the mold layer pattern 310 is exposed to form a cylindrical lower electrode 320 on an inner face of the opening 312. Simultaneously, the buffer layer pattern 330 may be formed on the opening 312 having the lower electrode 320.

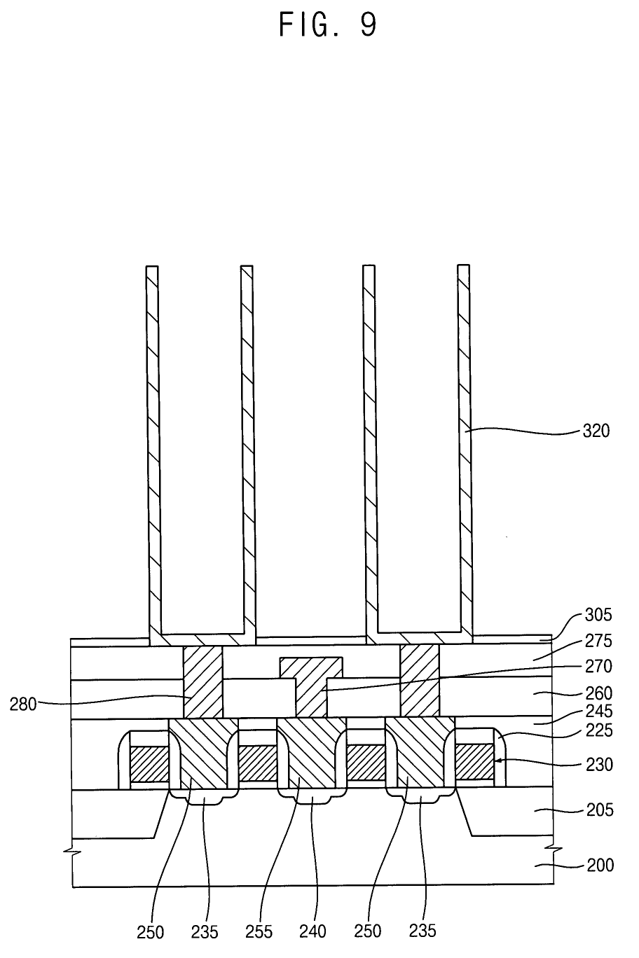

FIG. 9 is a diagram illustrating a cross-sectional view illustrating a process for forming the lower electrode according to example embodiments.

Referring to FIG. 9, the mold layer pattern 310 may be removed from the semiconductor substrate 200 using an etching solution for oxide. The lower electrode 320 may be exposed by the semiconductor substrate 200. The photoresist pattern, which is functioning as the buffer layer pattern 330, remaining on the lower electrode 320 may be removed by an ashing process and/or a stripping process. The cylindrical lower electrode 320 may be electrically connected to the third contact pad 280 of the semiconductor substrate 200. The lower electrode 320 may have a structure that has a higher aspect ratio and adjacently arranged patterns.

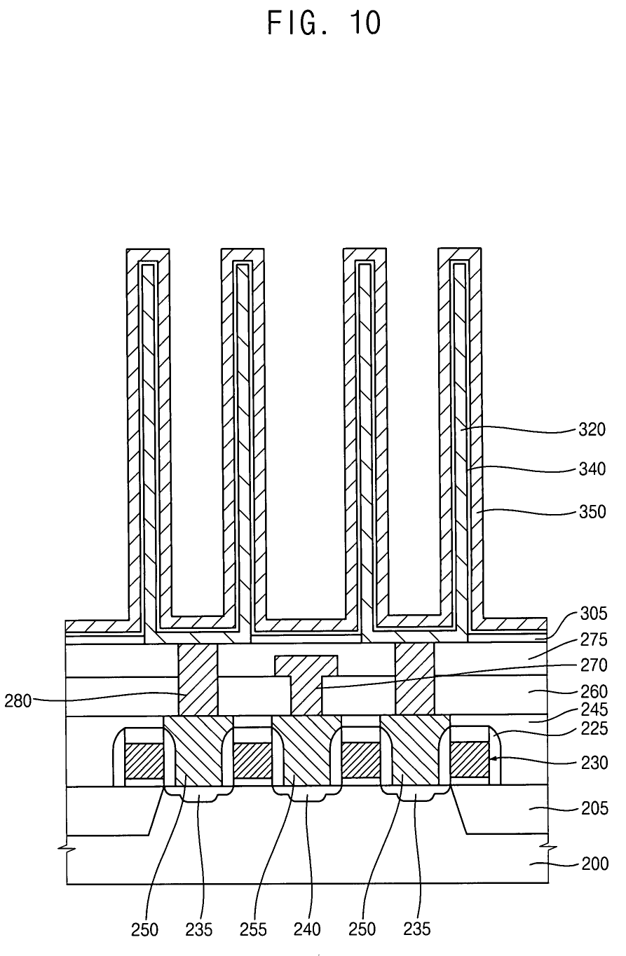

FIG. 10 is a diagram illustrating a cross-sectional view of a process for forming a dielectric layer and an upper electrode according to example embodiments.

Referring to FIG. 10, the dielectric layer 340 and the upper electrode 350 may be formed on the lower electrode 320.

The dielectric layer 340 may include oxide-nitride, oxide-nitride-oxide, metal oxide or the like. The metal oxide that has desirable leakage current characteristics and is capable of decreasing an equivalent oxide thickness (EOT) may be used for the dielectric layer 340. An ALD process for forming the dielectric layer 340 may include at least one cycle that includes applying a reaction material, purging, applying an oxidizing agent and purging again. The dielectric layer including the metal oxide may be formed on the lower electrode 320. The reaction material may include a metal precursor (e.g., a hafnium precursor or an aluminum precursor). The hafnium precursor may include tetrakis ethyl methyl amino hafnium (TEMAH), hafnium butyl oxide (Hf(O-tBu)₄) or the like. The aluminum precursor may include trimethyl aluminum (Al(CH₃)₃). The oxidizing agent may include O₃, O₂, H₂O, plasma O₂, remote plasma O₂ or the like.

After forming the dielectric layer 340, the upper electrode 350 may be formed on the resultant structure having the dielectric layer 340. The upper electrode 350 may include a material substantially the same as that of the lower electrode 320. Metal nitride having a higher degree of integration degree may be used for the upper electrode 350. The upper electrode 350 may be formed by a CVD process using titanium nitride. The upper electrode 350 including the titanium nitride may be formed by the CVD process at a temperature of about 700° C. using a reaction gas including a titanium tetrachloride (TiCl₄) gas, an ammonia (NH₃) gas or the like in order to form the upper electrode 350 with a denser structure.

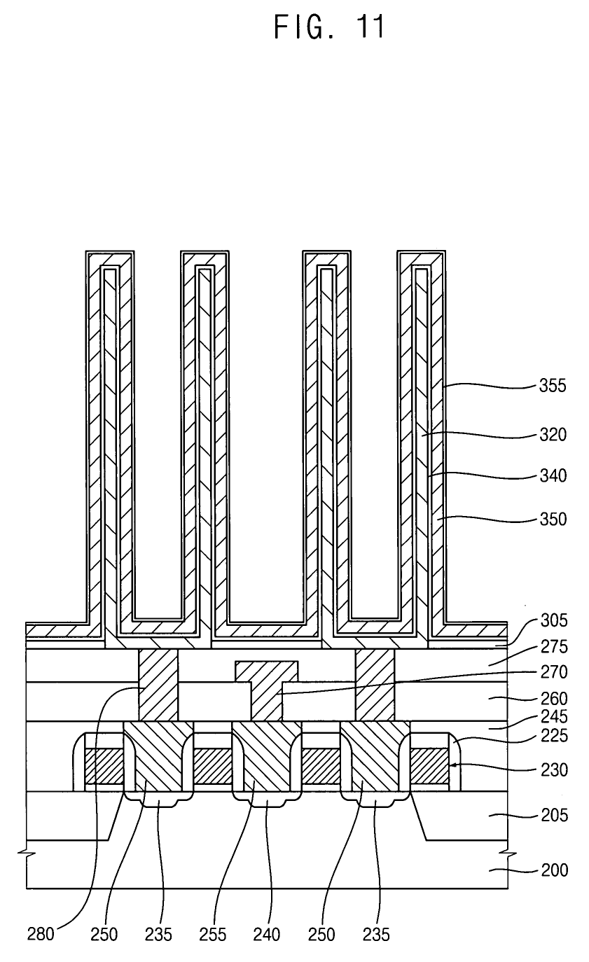

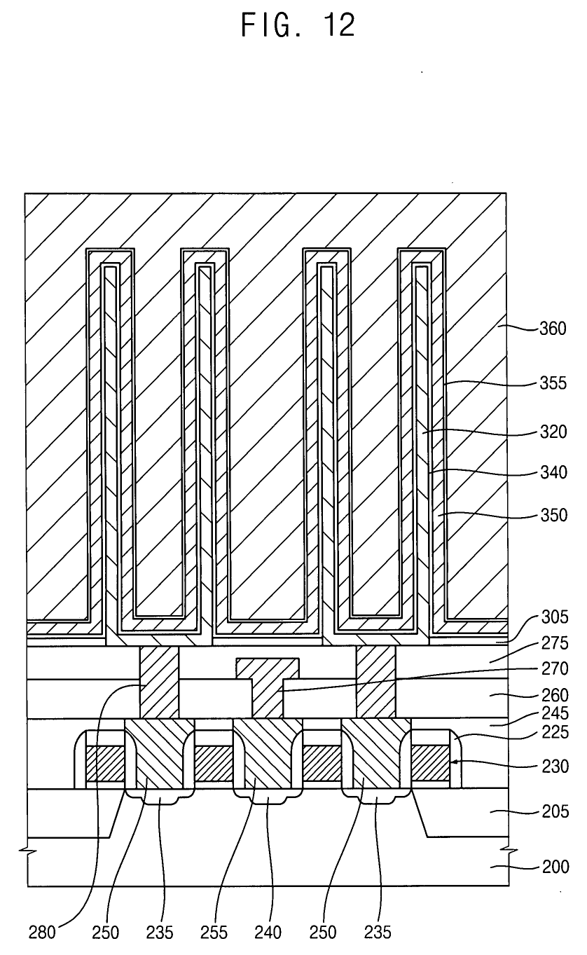

FIG. 11 is a diagram illustrating a cross-sectional view of a process for forming a barrier layer according to example embodiments.

Referring to FIG. 11, the barrier layer 355 prevents (or reduces) p-type impurities in a silicon germanium layer from infiltrating into the dielectric layer 340 through the upper electrode 350. The barrier layer 355 may be formed by thermally nitrifying or plasma-nitrifying a surface of the upper electrode 130. The barrier layer 355 may have a denser structure.

The barrier layer 355 may be formed by thermally treating a surface of the upper electrode 350 at a temperature of about 800° C. to about 1,100° C. under a gas atmosphere that includes N₂, NO, N₂O, NH₃ or the like. The barrier layer 355 may be formed by plasma-nitrifying the surface of the upper electrode 350 using plasma that is generated from a gas including N₂, NO, N₂O, NH₃ or the like.

FIG. 12 is a diagram illustrating a cross-sectional view of a process for forming a capping layer according to example embodiments.

Referring to FIG. 12, the capping layer 360 may be formed on the barrier layer 355. The capping layer 360 may be formed by depositing p-type doped silicon germanium on the barrier layer 355 by a CVD process. The capping layer 360 may include the p-type doped silicon germanium layer. The capping layer 360 may include a seed layer (not shown) and a p-type doped silicon germanium layer. The capping layer 360 is described above. Thus, any further description with respect to the capping layer 360 will be omitted herein for the sake of brevity. Because the capacitor includes the barrier layer 355, the boron in the capping layer 360 may not infiltrate in the dielectric layer 340.

Hereinafter, example embodiments will be described in the following examples and evaluation.

### Example 1

A lower electrode, a dielectric layer, an upper electrode, a barrier layer and a silicon germanium layer doped with boron were sequentially formed on a semiconductor substrate, which a silicon oxide layer having a thickness of 1,000 Å was formed to manufacture a capacitor. The lower electrode included a titanium nitride layer having a thickness of 150 Å. The dielectric layer included a hafnium/aluminum/hafnium layer having a thickness of 85 Å. The upper electrode included a titanium nitride layer having a thickness of 150 Å. The barrier layer had a thickness of 55 Å. The silicon germanium layer had a thickness of 1,200 Å. The upper electrode was formed by a PECVD process at a temperature of 530° C. The barrier layer was formed by a plasma nitrification process.

### Example 2

A lower electrode, a dielectric layer, an upper electrode, a barrier layer and a silicon germanium layer doped with boron were sequentially formed on a semiconductor substrate on which a silicon oxide layer having a thickness of 1,000 Å was formed to manufacture a capacitor. The lower electrode included a titanium nitride layer having a thickness of 150 Å. The dielectric layer included a hafnium/aluminum/hafnium layer having a thickness of 85 Å. The upper electrode included a titanium nitride layer having a thickness of 150 Å. The barrier layer had a thickness of 55 Å. The silicon germanium layer had a thickness of 1,200 Å. The upper electrode was formed by a CVD process at a temperature of 700° C. The barrier layer was formed by a plasma nitrification process.

### Comparative Example 1

A lower electrode, a dielectric layer, an upper electrode and a silicon germanium layer doped with boron were sequentially formed on a semiconductor substrate on which a silicon oxide layer having a thickness of 1,000 Å was formed to manufacture a capacitor. The lower electrode included a titanium nitride layer having a thickness of 150 Å. The dielectric layer included a hafnium/aluminum/hafnium layer having a thickness of 85 Å. The upper electrode included a titanium nitride layer having a thickness of 150 Å. The silicon germanium layer had a thickness of 1,200 Å. The upper electrode was formed by a PECVD process at a temperature of 530° C.

### Evaluation of the Diffusion of Boron

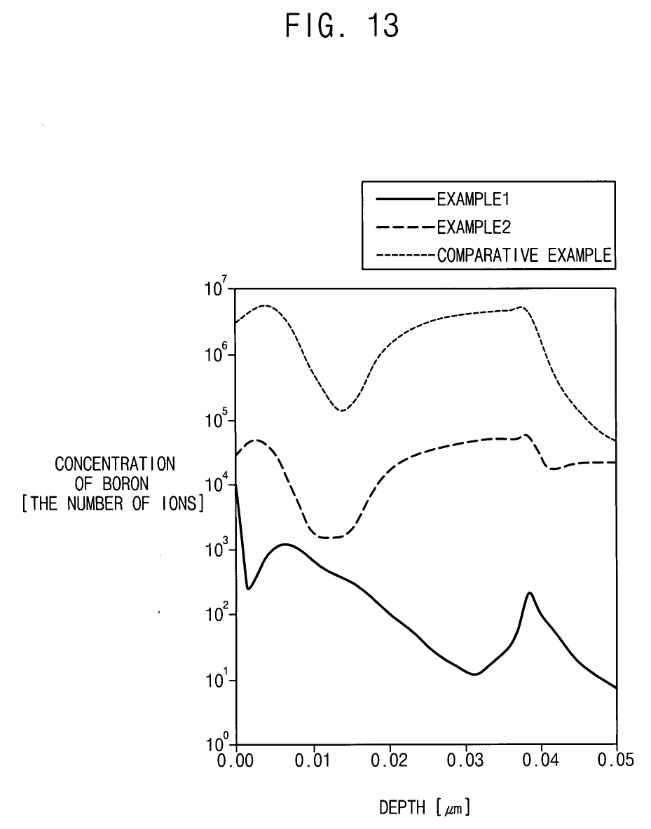

Concentrations of the boron in the dielectric layers in Example 1, Example 2 and Comparative Example 1 were measured using a secondary ion mass spectrometry (SIMS). The measured concentrations of the boron are shown in FIG. 13.

FIG. 13 is a graph illustrating the concentrations of the boron in the dielectric layers in Example 1, Example 2 and Comparative Example 1.

Referring to FIG. 13, 1.0×10⁵ or less boron atoms were measured on an upper face of the dielectric layer of the capacitor in Example 1. 1.0×10⁴ or less boron atoms were measured on a lower face of the dielectric layer of the capacitor in Example 1. 1.0×10³ or less boron atoms were measured on an upper face of the dielectric layer of the capacitor in Example 2. 1.0×10¹ or less boron atoms were measured on a lower face of the dielectric layer of the capacitor in Example 2. 1.0×10⁶ or less boron atoms were measured on an upper face of the dielectric layer of the capacitor in Comparative Example 1. 1.0×10⁵ or less boron atoms were measured on a lower face of the dielectric layer of the capacitor in Comparative Example 1.

As such, the barrier layer between the upper electrode and the capping layer including the boron prevents (or reduces) the boron in the capping layer from diffusing in the dielectric layer. The upper electrode may be formed by the CVD process at a temperature of 700° C. in order to suppress the diffusion of the boron.

According to example embodiments, the barrier layer including nitride may be formed on the upper electrode. The barrier layer may prevent (or reduce) the p-type impurities in the silicon germanium layer from infiltrating in the dielectric layer while performing subsequent thermal treatments. A charge-trapping site may not exist in the dielectric layer so that the dielectric layer may have increased reliability. Leakage currents may be suppressed such that the capacitor may have increased electrical characteristics.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of this invention as defined in the claims. In the claims, means-plus-function clauses are intended to cover the structures described herein as performing the recited function, and not only structural equivalents but also equivalent structures. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The present invention is defined by the following claims, with equivalents of the claims to be included therein.

What is claimed is:

1. A capacitor comprising:
a lower electrode;
a dielectric layer on the lower electrode, the dielectric layer having a uniform thickness;
an upper electrode on the dielectric layer, the upper electrode having a uniform thickness;
a capping layer on the upper electrode, the capping layer including a silicon germanium layer doped with p-type impurities; and
a barrier layer between the upper electrode and the capping layer preventing the p-type impurities from infiltrating into the dielectric layer.

2. The capacitor of claim 1, wherein the barrier layer includes a nitride layer having a thickness of about 30 Å to about 80 Å.

3. The capacitor of claim 1, wherein the capping layer includes a seed layer.

4. The capacitor of claim 3, wherein the seed layer is at least one selected from the group consisting of a silicon layer, a silicon germanium layer and a composite layer thereof.

5. The capacitor of claim 1, wherein the lower electrode has a cylindrical shape.

6. A method of manufacturing a capacitor, comprising:
forming a lower electrode on a substrate;
forming a dielectric layer having a uniform thickness on the lower electrode;
forming an upper electrode having a uniform thickness on the dielectric layer;
forming a barrier layer on the upper electrode, the barrier layer preventing p-type impurities from infiltrating into the dielectric layer; and
forming a capping layer on the upper electrode, the capping layer including a silicon germanium layer doped with the p-type impurities.

7. The method of claim 6, wherein forming the barrier layer includes thermally nitrifying a surface of the upper electrode.

8. The method of claim 7, wherein the thermal nitrification is performed at a temperature of about 800° C. to about 1,100° C. under a gas atmosphere that includes at least one selected from the group consisting of N₂, NO, N₂O and NH₃.

9. The method of claim 6, wherein forming the barrier layer includes plasma-nitrifying a surface of the upper electrode.

10. The method of claim 9, wherein the plasma nitrification includes:
generating plasma from a gas, wherein the gas is at least one selected from the group consisting of N₂, NO, N₂O and NH₃; and
applying the plasma to the surface of the upper electrode.

11. The method of claim 6, wherein forming the capping layer includes forming a silicon layer, wherein the silicon layer and the silicon germanium layer doped with the p-type impurities are formed in-situ.

12. The method of claim 6, wherein forming the capping layer includes a silicon germanium layer, wherein the silicon germanium layer and the silicon germanium layer doped with the p-type impurities are formed in-situ.

13. The method of claim 6, wherein forming the capping layer includes forming a silicon layer and a silicon germanium layer, wherein the silicon layer, the silicon germanium layer and the silicon germanium layer doped with the p-type impurities are formed in-situ.

14. A method of manufacturing a capacitor, comprising:
forming a conductive structure on the substrate;
forming a mold layer pattern on the substrate, the mold layer pattern having an opening that exposes an upper face of the conductive structure;
forming a conductive layer having a uniform thickness on the mold layer pattern and an inner face of the opening;
forming a buffer layer on the conductive layer filling up the opening;
forming a buffer layer pattern by partially removing the buffer layer until the conductive layer on the mold layer pattern is exposed; and
forming the capacitor according to the method of claim 1,
wherein the lower electrode is formed by etching the conductive layer on the mold layer pattern using the buffer layer pattern as an etching mask, and the lower electrode is exposed by removing the mold layer pattern and the buffer layer pattern.

15. The method of claim 14, wherein forming the barrier layer includes thermally nitrifying a surface of the upper electrode.

16. The method of claim 15, wherein the thermal nitrification is performed at a temperature of about 800° C. to about 1,100° C. under a gas atmosphere that includes at least one selected from the group consisting of N₂, NO, N₂O and NH₃.

17. The method of claim 15, wherein forming the barrier layer includes plasma-nitrifying a surface of the upper electrode.

18. The method of claim 17, wherein the plasma nitrification includes:
generating plasma from a gas, wherein the gas is at least one selected from the group consisting of N₂, NO, N₂O and NH₃; and
applying the plasma to the surface of the upper electrode.

19. The method of claim 14, wherein forming the capping layer includes forming a silicon layer, wherein the silicon layer and the silicon germanium layer doped with the p-type impurities are formed in-situ.

20. The method of claim 14, wherein forming the capping layer includes a silicon germanium layer, wherein the silicon germanium layer and the silicon germanium layer doped with the p-type impurities are formed in-situ.

21. The method of claim 14, wherein forming the capping layer includes forming a silicon layer and a silicon germanium layer, wherein the silicon layer, the silicon germanium layer and the silicon germanium layer doped with the p-type impurities are formed in-situ.
